(19) United States
(12) Patent Application Publication
(10) Pub. No.: US 2013/0251917 A1
(43) Pub. Date: Sep. 26, 2013

(54) Device for Plasma Coating Product Containers, Such as Bottles

(71) Applicant: KRONES AG, Neutraubling (DE)

(72) Inventors: Jochen Krueger, Hagelstadt (DE); Martin Watter, Regensburg (DE)

(73) Assignee: KRONES AG, Neutraubling (DE)

(21) Appl. No.: 13/761,405

(22) Filed: Feb. 7, 2013

(30) Foreign Application Priority Data
Mar. 23, 2012 (DE) 102012204690.9

(51) Int. Cl. C23C 16/52

(52) U.S. Cl. CPC C23C 16/52
USPC 427/569; 118/723 E; 118/712

(57) ABSTRACT

The disclosure relates to a device and a method for plasma coating product containers, in particular bottles, the device preferably being a rotary machine comprising a control unit, one or several electrode segments for plasma coating, wherein the electrode segment or each one of the electrode segments can receive at least one product container, and electrodes for coupling out high-frequency radiation. The control unit can automatically control plasma coating in one or each one of the electrode segments depending on process parameters.

### FIELD OF THE INVENTION

The disclosure relates to a device for plasma coating product containers, such as bottles.

### BACKGROUND

There are some devices for plasma coating in prior art. For example, a method and a device for treating substrates in a rotary plant are known from DE 10 2004 028 369. This device can be in particular used for coating plastic containers in a rotary plant. Here, several treatment devices are provided on the rotary machine and carry out several process phases depending on their angular position on the rotary machine. It is possible to variably adjust the angular position for at least one of the different process phases depending on the predetermined rotational speed of the rotary machine. The advantage of this device is that the process duration for each process phase can be kept constant, even if the rotational speed of the rotary machine changes.

Moreover, WO 03/100120 shows a device and a method for treating workpieces. The advantage of this method is that a plurality of treatment devices with at least one workpiece to be treated each is provided.

Furthermore, DE 10 2005 015 063 shows a device and a method for automatically creating control instructions for rotary machines. This disclosure provides a system which permits the user to create a program code for controlling a rotary machine via a structured menu navigation. This is done at two menu levels, at the first one, a segment on the rotary machine being defined, and at the second one, the function of the rotary machine or the processing stations being determined. This permits a logic partition of the circulating periphery into individual segments within which certain functions can be controlled.

It is therefore an object of the present disclosure to develop a device for plasma coating product containers, such as bottles, which permits high flexibility and a minimization of rejects.

According to some aspects of the present disclosure, this object is achieved by the device characterized in claim 1 and the method described in claim 11. The dependent claims contain functional embodiments of the invention.

The present disclosure is characterized in that each of the electrode segments can receive at least one product container and the control unit can automatically control the plasma coating in one or in each one of the electrode segments or in selectable electrode segments depending on process parameters. It is therefore on the one hand possible to coat several product containers in one single process step in an electrode segment, and it is furthermore possible to adapt the course of the process to changing external process parameters. This is in particular advantageous if accidental changes of process parameters occur, such as the missing of single product containers or jams upstream or downstream of the device.

In one embodiment, the control unit can adjust the power of high-frequency radiation to values between 0 watts and a value L which is employed at a maximum product container population number n and normal operating speed b which normally is the maximally provided operating speed. Thereby, a preferably ideal adaptation of the power of high-frequency radiation to changed process parameters can be achieved.

In another embodiment, a speed sensor is provided which can measure a current transport speed v of the product containers and forward the value to the control unit, or a current transport speed v can be predetermined in the control unit and the control unit can correspondingly control a drive for the product containers. This can assist in adapting the plasma coating process, in particular in case of jams of product containers upstream or downstream of the device, such that an aggravation of the jam after the containers have passed the device is prevented, and/or a device is prevented from remaining empty in case of a jam of product containers upstream of the device.

In another embodiment, the control unit controls the power of high-frequency radiation in one or in each one of the electrode segments depending on the current transport speed v of the product containers, such as the rotational speed in the rotary machine. This permits to always deposit the same amount of energy in the respective product container in each plasma coating process of each product container via the high-frequency radiation coupled in via the electrodes.

In another embodiment, the control unit adjusts the power L₁ of high-frequency radiation to

$${L}_{1} = \frac{v}{b} L$$

according to or based on the ratio

$$\frac{v}{b}$$

of the current transport speed v and the normal operating speed b. This permits, in particular at a lower current transport speed b compared to b and thereby an extended exposure time of the product containers in the device for plasma coating, to nevertheless deposit the same amount of energy in the product containers compared to normal operating speed.

In another embodiment, a detection device for product containers, such as a light barrier, is provided and can transmit signals relating to the entry of product containers into one or into each electrode segment to the control unit which can, based on these signals, determine a number m of the product containers in one or each electrode segment. This permits a continuous control of the number of product containers in one or in each one of the electrode segments and permits the determination of the energy deposited in the product containers depending on the power of high-frequency radiation which is coupled out through the electrodes.

In another embodiment, the control unit controls the power of the electrodes in one or in each one of the electrode segments depending on the number m of product containers. This permits an adaptation of the power of high-frequency radiation which is coupled out by the electrodes and thus permits, for example, a reduction of the electrode power in the presence of only a few product containers as the maximum product container population number in one or each one of the electrode segments.

In another embodiment, the control unit adjusts the power 4 of high-frequency radiation in one or in each one of the electrode segments to

$${L}_{2} = \frac{m}{N} L$$

according to or based on the ratio

$$\frac{m}{N}$$

of the number of product containers m in one or each electrode segment and the maximum product container population number N in one or each electrode segment. Even with a low number of product containers in one or each one of the electrode segments, this also permits to deposit the same amount of energy in each of the product containers over the duration of the complete plasma coating process, compared to the maximum product container population number during the plasma coating process.

In another embodiment, the control unit adjusts the power L̅ of high-frequency radiation in one or each electrode segment according to or based on

$$\overline{L} = \frac{v}{b} \cdot \frac{m}{N} \cdot L .$$

Despite a reduced transport speed v, compared to the normal operating speed b, and/or a reduced number of product containers m compared to the maximum product container population number N, this permits to nevertheless deposit the same amount of energy in the product containers to be coated over the complete duration of the plasma coating process.

In another embodiment, the control unit can terminate the coupling out of high-frequency radiation from the electrodes of the electrode segment or each electrode segment if either the current transport speed of product containers is 0 ms⁻¹, where at least one product container, but preferably the maximum product container population number, is located in one or each one of the electrode segments; or if no product container is located in one or each one of the electrode segments. This on the one hand contributes to it being possible to stop the plasma coating operation in case of a standstill of the device with product containers simultaneously remaining in the electrode segments to prevent the total amount of energy which is deposited in the product containers from exceeding the maximally provided amount of energy, thereby minimizing rejections. Thus, the device does not have to be run empty after a standstill and the number of rejects is reduced. In case of an empty electrode segment, it can moreover be avoided that mechanical components are damaged by electric arcing due to coupled-in high-frequency radiation.

For example, by using this device, a method can be realized in which, with the aid of a control unit and one or several electrode segments, product containers, as in particular bottles, can be coated during a plasma coating process, where each one of the electrode segments receives at least one product container and comprises electrodes for coupling out high-frequency radiation. The method is characterized in that the plasma coating is automatically controlled by the control unit in one or each one of the electrode segments depending on process parameters. This permits a precise adaptation of the plasma coating process to changing process parameters and thus a reduced quality variance in the plasma coating of product containers, thereby reducing rejects.

In one embodiment, the method is characterized in that it can be optionally realized with one or several ones of the following features: a speed sensor determines the current speed of the product containers to be coated; or the control unit predetermines a current transport speed v and controls a drive for the product containers; a detection device for product containers, such as a light barrier, transmits signals relating to the entry of product containers into one or each electrode segment to the control unit which determines a number m of the product containers in one electrode segment. These features permit, by suited combination, high flexibility of the method with respect to changing process parameters. For example, at a lower transport speed and/or with a lower number of product containers in one or each electrode segment, the power can be reduced such that the energy deposited in the product containers always remains the same while they are passing the complete plasma coating process. Furthermore, the formation of secondary plasmas and the damage of mechanical components due to arcing can be reduced. Moreover, a melting of product containers due to excessive deposited energy during the plasma coating process can be avoided.

In another embodiment, the method is characterized in that the control unit terminates the coupling out of high-frequency radiation from the electrodes of the or of each electrode segment when either the transport speed of the product containers is 0 ms⁻¹, wherein at least one product container, but preferably the maximum product container population number, is located in one or each one of the electrode segments; or if no product container is located in one or each one of the electrode segments. It is just in case of a standstill of the machine that this permits the termination of the plasma coating operation to prevent the amount of energy deposited in the product containers from exceeding the intended amount of energy. On the other hand, in case of not existing product containers, it permits to prevent damages of components due to the nevertheless coupled-in high-frequency radiation.

Additional aspects and/or advantages of the devices and methods disclosed herein will be apparent upon review of the following detailed description and the attached figures.

### BRIEF DESCRIPTION OF THE FIGURES

FIG. 1 is a complete plan view of a preferred embodiment of the device.

FIG. 2 is a representation of the feeding of high-frequency radiation with different numbers of product containers in one electrode segment.

FIGS. 3A and 3B are representations of the coupling out of high-frequency radiation with different transport speeds of the product containers.

FIG. 4 shows a further preferred embodiment.

FIG. 5 shows a further preferred embodiment.

FIGS. 6A and 6B are representations of the plasma coating operation

FIG. 7 shows a further preferred embodiment.

### DETAILED DESCRIPTION

The plasma coating of products, in particular product containers, such as bottles, is achieved by means of a device for plasma coating with one or several electrode segments and a control unit. Identical or functionally similar components are indicated with reference numbers having the same last two digits but increased or decreased by hundreds corresponding to the figure number (e.g. mountings 180, 280, 380, 480, 580, 680, 780).

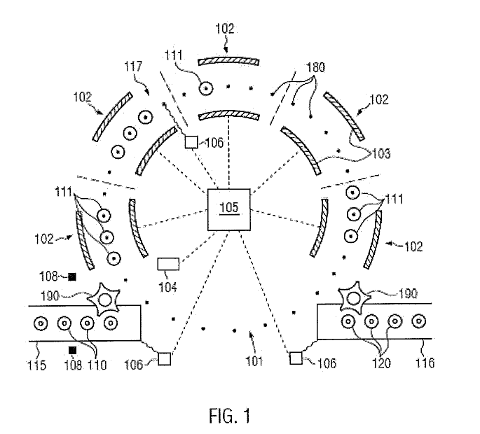

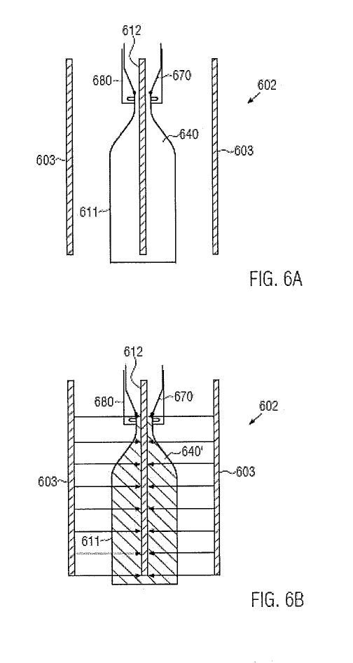

FIG. 1 schematically shows the assembly of a preferred embodiment of a device 101 according to the disclosure for plasma coating product containers. Here, the uncoated product containers 110 are located on a conveying belt 115 leading to the device 101. The uncoated product containers 110 can be relocated, for example by means of a guide starwheel 190, onto the coating line 117 which leads through the device for plasma coating 101. If the product containers 111 to be coated are located in the coating line 117 which leads through the device for plasma coating 101, the progression of the product containers 111 to be coated is preferably effected by transporting them suspended in respective mountings 180 through the coating line. Here, the mountings 180 are preferably designed such that they hold the product containers at their necks. The mountings 180 are only schematically indicated in FIG. 1. FIG. 6 refers to a preferred assembly. The product containers 111 to be coated pass, with the mountings 180, through one or several electrode segments 102 where electrodes 103 are located which are preferably mounted in parallel to the moving direction of the product containers. In these electrode segments 102, the plasma coating process of the product containers 111 to be coated takes place. After the product containers have passed through the device for plasma coating 101, the now coated product containers 120 reach, for example, a further guide starwheel 190 which can relocate the now coated product containers 120 from the coating line 117 onto a conveying belt 116 leading away from the device for plasma coating 101, the connection of the coated product containers 120 to the mountings 180 being released beforehand. The conveying belts 115 and 116 are driven by drives 106. The mountings 180 in the coating line 117 can also be driven by such a motor 106, as can be seen in FIG. 1. The speed of the product containers 111 to be coated in the device for plasma coating 101 is measured by means of a speed sensor 104. The entry of an uncoated product container 110 into the device for plasma coating 101 is preferably detected by means of a detection device for product containers, such as a light barrier 108. A control unit 105 can evaluate the data of the speed sensor 104 and the detection device 108 and control the electrodes 103 of the electrode segments 102 and the drives 106 of the conveying belts 115 and 116 as well as of the mountings 180 in the coating line 117.

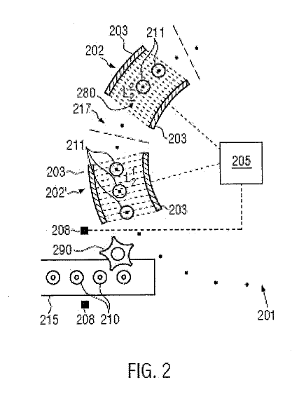

FIG. 2 shows the course of the plasma coating process depending on the number of product containers 211 to be coated which are located, during the plasma coating process, within one or each one of the electrode segments 202. The uncoated product containers 210 deviated, for example by the guide starwheel 290, from the transport line 215 into the coating line 217 are detected by the detection device 208. If there is a gap in the line of uncoated product containers 210, this gap will also be present in the region of the device for plasma coating 201. The corresponding mounting 280 which is located at the place of the not present product container to be coated is now vacant. This means that the coupled-in high-frequency radiation with its total power L deposits energy in a lower number than the provided maximum product container population number N. Thus, more energy than intended falls onto each of the other product containers 211 to be coated in the corresponding electrode segment 202 with an unchanged power of high-frequency radiation. To prevent this, the control unit 205 controls, upon evaluation of the signals of the detection device 208 of the electrode segment 202 which contains a number m of product containers 211 to be coated which is smaller than the maximum product container population number N, the coupled-in power so that the coupled-in power 4 is smaller by the factor

$$\frac{m}{N}$$

than the power coupled in with the maximum product container population number. If, however, the control unit 205 detects, upon evaluation of the signals of the light barrier 208, that the maximum product container population number is present in one electrode segment 202′, meaning that for each available mounting 280, one product container 211 to be coated is present, the power 4 provided for normal operation is used in the coupling out of high-frequency radiation.

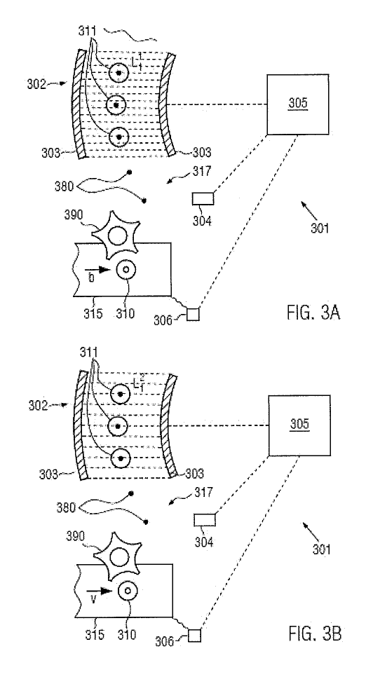

FIGS. 3A and 3B show the plasma coating process depending on the current speed v of the product containers 311 to be coated. To simplify things, the gapless availability of uncoated product containers 310 in the transport line 315 leading to the device for plasma coating 301 is assumed for this representation. The uncoated product containers 310 are again guided onto the coating line 317 leading through the device for plasma coating 301, possibly by the guide starwheel 390, and supplied to a mounting 380, the conveying belt 315 and the mountings in the coating line 317 preferably having the same speeds v. Reference is now made to FIG. 3A where the uncoated product containers 310 and the product containers 311 to be coated move at the normal operating speed b on the conveying belt 315 and in the coating line 317. The control unit 305 either determines by means of the speed sensor 304 that the uncoated product containers 310 and the product containers 311 to be coated move on the conveying belt 315 and in the coating line 317 at normal transport speed b, or it determines, by controlling the drive 306, the speed at which the uncoated product containers 310 and the product containers 311 to be coated move on the conveying belt 315 and in the coating line 317. In either case, the speed of the product containers is equal to the normal transport speed b (FIG. 3A). If the product containers 311 to be coated are located within the device for plasma coating 301 in one of the or in the electrode segment(s) 302, the control unit 305 controls the coupling-out of high-frequency radiation from the electrodes 303 in the electrode segment 302, such that the power L₁¹ corresponding to normal transport speed b is coupled out, whereby, within the exposure time of the product containers 311 to be coated in the electrode segment 302 determined by the normal transport speed b, a predetermined amount of energy is coupled into the plasma which is ignited in the product containers 311 to be coated by coupling in high-frequency radiation.

Reference is made now to FIG. 3B. Here, the current transport speed v of the uncoated product containers 310 on the conveying belt 315 and the product container 311 to be coated in the coating line 317 is lower than the normal transport speed b. The control unit 305 obtains corresponding information either by the speed sensor 304 which measures the speed of the product containers 311 to be coated in the coating line 317, or by the control unit 305 directly controlling the drive 306 of the conveying belt 315 and the mountings 380 in the coating line 317 and thus adjusting the speed v<b. To prevent excessive energy from being deposited, during the exposure time of the product containers 311 to be coated in the electrode segment or segments 302 caused to be longer by the lower speed v, in the plasma located in the product containers 311 to be coated and thus in the product containers 311 to be coated, the control unit 305 can control the electrodes 303 of the electrode segment or of each electrode segment 302 such that the power of high-frequency radiation L₁² coupled out from them is lower by the factor

$$\frac{v}{b}$$

than that in the plasma coating process of FIG. 3A. Thereby, despite the longer exposure time of the product containers 311 to be coated in the electrode segment 302, the total amount of energy deposited in the product containers 311 to be coated is as high as that in a normal operation case.

The processes described in FIG. 2 and FIGS. 3A and 3B can be combined by suited programming of the control unit 205 or 305, respectively, to obtain a resulting power L̅. Due to technical limits, the above-described adjustment of the powers Lᵢ^{j} cannot be effected with any desired precision on the basis of the prefactors by the control unit 205 or 305, respectively. Preferably, the power can therefore be controlled step by step. This is preferably mainly true for the prefactor

$$\frac{m}{N}$$

defined by the number of product containers as here the possible prefactors and thus the steps to be adjusted with a given maximum product container population number N are known and can be already present, for example, as stored data record. The adaptation of the power to the current transport speed v is preferably possible with a finer graduation, where here it is also obvious to a person skilled in the art that this graduation cannot be arbitrarily precise. It can be predetermined, for example, that the power actually predetermined by the control deviates from the calculated powers L₁, L₂, L̅ within a range of, for example, up to 5% or 10%.

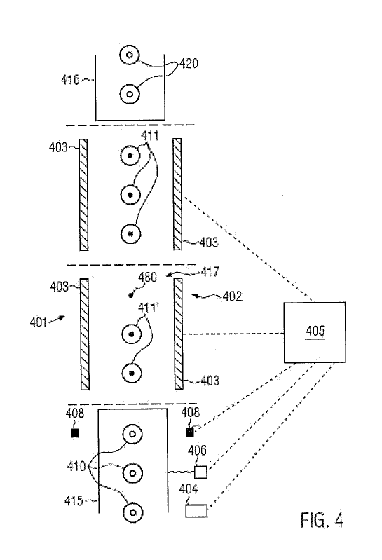

FIG. 4 is another possible embodiment which represents a device for plasma coating 401 product containers 411 to be coated. Here, the electrode segments 402 and in particular the electrodes 403 are arranged in parallel to a straight coating line 417. This can render superfluous the guidance of uncoated product containers 410 and product containers 420 to be coated in the respective conveying belts 415 and 416 with the aid of, for example, guide starwheels.

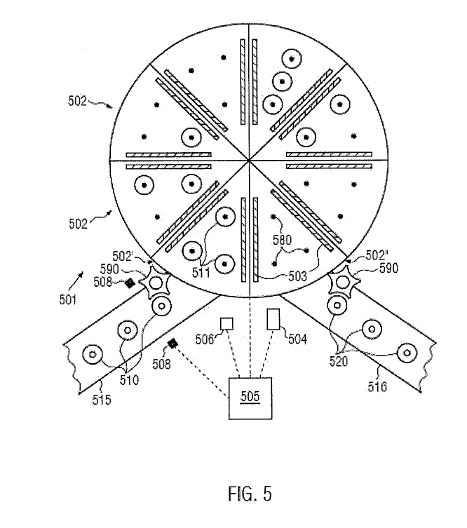

In another possible embodiment which is shown in FIG. 5, the device for plasma coating 501 includes a rotary rail which is divided into several, at least, however, two electrode segments 502. The conveying belt 515 which guides the uncoated product containers 510 to the device for plasma coating 501 and the conveying belt 516 which guides the coated product containers 520 away from the device for plasma coating 501 are preferably arranged such that the current electrode segment 502″ which transfers the coated product containers 520 to the conveying belt 516 is adjacent to the electrode segment 502′ which receives the uncoated product containers 510 from the transport line 515. This ensures that the product containers 511 to be coated have a preferably long exposure time in the rotary machine. The arrangement of the electrodes 503, the product containers 511 to be coated and the mountings 580 is here chosen for illustration purposes. It would be obvious to a person skilled in the art that there are other, possibly better suited possibilities of arranging the electrodes 503, the mountings 580 and the product containers 511 to be coated within one or each electrode segment 502. The positioning of the conveying belts 515 and 516 relative to the device for plasma coating 501 is here also only given for illustration purposes. It would be also conceivable, for example, that the conveying belts 515 and 516 run perpendicularly to the plane of projection and the rotary machine and that the bottles are introduced into the electrode segments 502 by possible guide starwheels.

FIGS. 6A and 6B show a possible embodiment of the operation of plasma coating a product container 611 to be coated in one of the electrode segments 602. In FIG. 6A, a product container 611 to be coated is represented in which a lance 612 located in each mounting 680 is introduced. Furthermore, the mounting 680 grips around the neck of the product container 611 to be coated. Within the mounting 680, a process gas unit 670, which can be coupled, for example, by means of a valve to the opening of the product container 611 to be coated, can take care of the supply of the process gas 640 for plasma coating and of an evacuation for a density of the process gas 640 to be low compared to the exterior of the product container 611 to be coated. In FIG. 6B, an electric field is applied between the lance 612 and the electrodes 603, so that high-frequency radiation of a predetermined power L can be coupled out. Here, the lance 612 functions as a further electrode. The high-frequency radiation can be either coupled out from the electrodes 603, the lance 612 being connected to ground, or the high-frequency radiation can be coupled out from the lance 612, where then the electrodes 603 are connected to ground.

Due to the low particle number density of the process gas 640′ within the product container 611 to be coated, the power L of the high-frequency radiation is converted by igniting a plasma of the process gas 640′. As the conditions necessary for the ignition of a plasma of the process gas 640′ are preferably given only within the product container 611 to be coated, the total power L of high-frequency radiation is only converted within the product container.

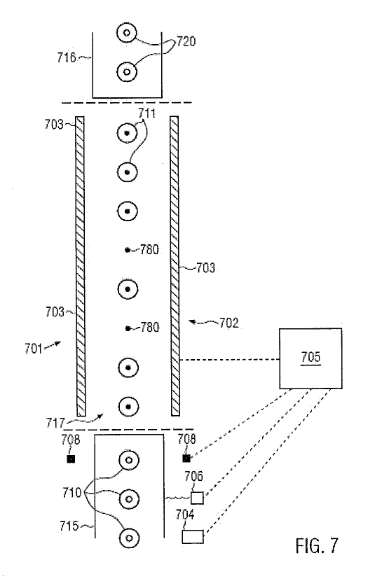

FIG. 7 shows another possible embodiment of the device for plasma coating 701. Here, the device 701 consists of only one electrode segment 702 in which mountings 780 for product containers 711 to be coated are guided. Here, too, the determination of the entry of an uncoated product container 710 from the transport line 715 into the coating line 717 within the device for plasma coating 701 is preferably effected by means of a detection device for product containers, for example a light barrier 708. The transport speed of the product containers can be measured by means of a speed sensor 704. Furthermore, conveying belts 715 and 716 are driven, like the mountings 780, by means of a drive 706. The control of the electrodes 703, the evaluation of the signals of the detection device 708 and the speed sensor 704, and the control of the drive 706 are effected by means of a control unit 705.

What is claimed is:

1. A device for plasma coating product containers, comprising:
a control unit,
at least one electrode segment for plasma coating, where each electrode segment can receive at least one product container, and
electrodes for coupling out high-frequency radiation,
wherein the control unit can automatically control the plasma coating in at least one of the electrode segments depending on process parameters.

2. The device of claim 1, wherein the control unit can adjust the power of high-frequency radiation to values between 0 W and the value L which is used with the maximum product container population number N and at the normal operating speed b.

3. The device of claim 1, wherein a speed sensor is provided which can measure a current transport speed v of the product containers and forward the value of v to the control unit.

4. The device of claim 3, wherein the control unit can control the power of high-frequency radiation in at least one of the electrode segments depending on the current transport speed v of the product containers.

5. The device of claim 4, wherein the control unit can adjust the power L₁ of high-frequency radiation to
$${L}_{1} = \frac{v}{b} L$$
according to the ratio
$$\frac{v}{b}$$
of the current transport speed v and the normal operating speed b.

6. The device of claim 1, further comprising at least one detection device for product containers which can transmit signals relating to the entry of product containers into at least one electrode segment to the control unit which can determine, based on the signals, a number m of the product containers in the at least one electrode segment.

7. The device of claim 6, wherein the control unit can control the power of high-frequency radiation in electrode segment depending on the number m.

8. The device of claim 7, wherein the control unit can adjust the power of high-frequency radiation in the electrode segment to
$${L}_{2} = \frac{m}{N} L$$
according to the ratio
$$\frac{m}{N}$$
or the number or product containers m and the maximum product container population number N in at least one electrode segment.

9. The device of one of claim 1, wherein the control unit can adjust the power L̅ of high-frequency radiation in at least one electrode segment according to
$$\overline{L} = \frac{v}{b} \cdot \frac{m}{N} \cdot L .$$

10. The device of claim 1, wherein the control unit can terminate the coupling-out of high-frequency radiation from the electrodes, if the current transport speed of product containers is v=0 ms⁻¹, where at least one product container is in at least one of the electrode segments.

11. A method for plasma coating product containers by means of a device comprising a control unit and at least one electrode segment for plasma coating, each electrode segment receiving at least one product container, and electrodes for coupling out high-frequency radiation, the method comprising the step of:
automatically controlling the plasma coating by the control unit in at least one electrode segment depending on process parameters.

12. The method of claim 11, further comprising the step of:
determining the current transport speed v of the product containers with a speed sensor.

13. The method of claim 11, further comprising the step of:
adjusting the power of high-frequency radiation in one or each one of the electrode segments with the control unit depending on the current transport speed v of the product containers, the normal operating speed b, the number m of product containers in at least one electrode segment, and the maximum product container population number N in at least one electrode segment.

14. The method of claim 11, further comprising the steps of:
terminating the coupling out of high-frequency radiation from the electrodes with the control unit, if:
the transport speed of the product containers is v=0 ms⁻¹, where at least one product container is located in at least one of the electrode segments; or
no product container is located in at least one electrode segment.

15. The device of claim 1, wherein the product containers are bottles.

16. The device of claim 1, wherein the device is a rotary machine.

17. The device of claim 1, wherein the control unit can automatically control the plasma coating in selectable electrode segments depending on process parameters.

18. The device of claim 1, wherein the control unit can predetermine a current transport speed v and control a drive for the product containers.

19. The device of claim 4, wherein the device is a rotary machine and the current transport speed v of the product containers is a rotational speed in the rotary machine.

20. The device of claim 6, wherein the at least one detection device comprises a light barrier.

21. The device of claim 6, wherein the at least one detection device can transmit signals relating to the entry of product containers into each electrode segment to the control unit which can determine, based on the signals, a number m of the product containers in each electrode segment.

22. The device of claim 10, wherein the control unit can terminate the coupling-out of high-frequency radiation from the electrodes if the current transport speed of product containers is v=0 ms⁻¹, where the maximum product container population number N is in at least one of the electrode segments.

23. The device of claim 1, wherein the control unit can terminate the coupling-out of high-frequency radiation from the electrodes if no product container is located in at least one electrode segment.

24. The method of claim 11, further comprising the steps of:
predetermining a current transport speed v with the control unit; and
controlling a drive for the product containers with the control unit.

25. The method of claim 11, further comprising the step of:
transmitting signals relating to the entry of product containers into at least one electrode segment to the control unit with a detection device for product containers; and
determining a number m of product containers in one electrode segment with the control unit.
